(19) United States
(12) Patent Application Publication
(10) Pub. No.: US 2008/0150769 A1
(43) Pub. Date: Jun. 26, 2008

(54) KEY INPUT ELECTRONIC DEVICE

(75) Inventor: Hitoshi IMAMURA, Hyogo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: SANYO ELECTRIC CO., LTD., Osaka (JP)

(21) Appl. No.: 11/960,130

(22) Filed: Dec. 19, 2007

(30) Foreign Application Priority Data
Dec. 20, 2006 (JP) 2006-342989

(51) Int. Cl. H03K 17/94

(52) U.S. Cl. 341/34

(57) ABSTRACT

The present invention provides a key input electronic device controlled in operation by a control circuit to which input signals in accordance with input operations are fed, and including a key input unit including an array of a plurality of switches; a key sheet detachably provided over the key input unit; and a sheet identification chip attached to the key sheet. The key sheet has a plurality of press operation portions for pressing and operating the switches, defined by forming on the sheet body a plurality of easily displaceable portions corresponding to the switches. The control circuit changes the image display control based on the sheet identification information recorded on the sheet identification chip.

The priority application Number 2006-342989 upon which this patent application is based is hereby incorporated by reference.

### BACKGROUND OF THE INVENTION

1. Field of the Invention

The present invention relates to key input electronic devices such as portable telephones, electronic organizers, game machines, etc. which are controlled in operation by a control circuit to which input signals in accordance with key operations are fed.

2. Description of Related Art

In recent years, portable telephones have been becoming multifunctional, having not only an ordinary telephone communication function, but also multiple additional functions such as a music reproduction function, television broadcasting reception function, game function, etc. Such portable telephones capable of switching and performing multiple functions utilize operation keys, such as ten keys, for the telephone communication function as function keys in accordance with an additional function to be performed.

In this case, the operation keys would provide poor operationality if they remain indicating numerals, for example. Accordingly, there has been proposed a portable telephone including a keypad with a plurality of operation keys and a key case with a plurality of holes through which the operation keys of the keypad are to protrude to be operable, wherein the keypad and the key case can be replaced by a user to thereby change the key indication at the user's wish.

However, there have been problems. The above-described portable telephone has the replacement parts, keypad and key case, put on top of the telephone body. This increases the thickness, preventing the portable telephone from being made thinner. Besides, the replacement is complicated and time-consuming.

### SUMMARY OF THE INVENTION

The present invention provides a key input electronic device controlled in operation by a control circuit to which input signals in accordance with input operations are fed, and including:

a key input unit provided on the device body and including an array of a plurality of switches;

a key sheet including a sheet body detachably provided over the key input unit, the sheet body having a plurality of easily deformable press operation portions formed corresponding to the switches of the key input unit for pressing and operating the switches;

a sheet information portion provided on the key sheet; and

a sheet identifying portion for identifying the key sheet based on the sheet information portion,

wherein the key input unit and the sheet identifying portion are connected to the control circuit, and the control circuit is configured to change the operation based on the result identified by the sheet identifying portion.

For the above-described key input electronic device of the present invention, multiple key sheets are prepared having respective key indications corresponding to multiple executable functions. The key sheets each have a sheet information portion given identification information for identifying the key sheets.

Users select one of the key sheets in accordance with a function to be performed, and attach that key sheet to the device body. This causes the plurality of press operation portions formed on the key sheet to be opposed to the plurality of respective switches of the key input unit of the device body, and connects the sheet information portion provided on the key sheet to the sheet identifying portion of the device body.

The control circuit of the device body reads out the sheet identification information given to the sheet information portion via the sheet identifying portion, and identifies the key sheet. In accordance with the identified result, the control circuit then changes operations in accordance with input signals from the key input unit (for example, image display control or function) for each of the key sheets.

When any one or more of the press operation portions of the key sheet are operated in this state, one or more switches of the key input unit turn on, and an input signal based on the key operation is fed to the control circuit.

As a result, the control circuit performs the operation after the change based on the input signal from the key input unit.

### BRIEF DESCRIPTION OF THE DRAWINGS

FIG. 1 is a perspective view of a portable telephone of the present invention;

FIG. 2 is an exploded perspective view of an operation side body;

FIG. 3 is a plan view of a key input device;

FIG. 4 is a front view showing guide grooves and switches provided on the operation side body;

FIG. 5 is a perspective view of a sheet identification chip attached to a key sheet;

FIG. 6 is a back view of the same;

FIG. 7 is a block diagram showing an electrical configuration of the portable telephone of the present invention;

FIG. 8 is a plan view of another key sheet;

FIG. 9 is a plan view of still another key sheet;

FIG. 10 is a plan view of still another key sheet;

FIG. 11 is a plan view of still another key sheet;

FIG. 12(a) and FIG. 12(b) are each a plan view showing an example of the display screen;

FIG. 13(a), FIG. 13(b) and FIG. 13(c) are each a plan view showing another example of the display screen;

FIG. 14(a) and FIG. 14(b) are a plan view and a sectional view, respectively, showing another example of the key sheet; and

FIG. 15(a) and FIG. 15(b) are a plan view and a sectional view, respectively, showing still another example of the key sheet.

### DETAILED DESCRIPTION OF THE INVENTION

A foldable portable telephone embodying the present invention will be specifically described below with reference to the drawings.

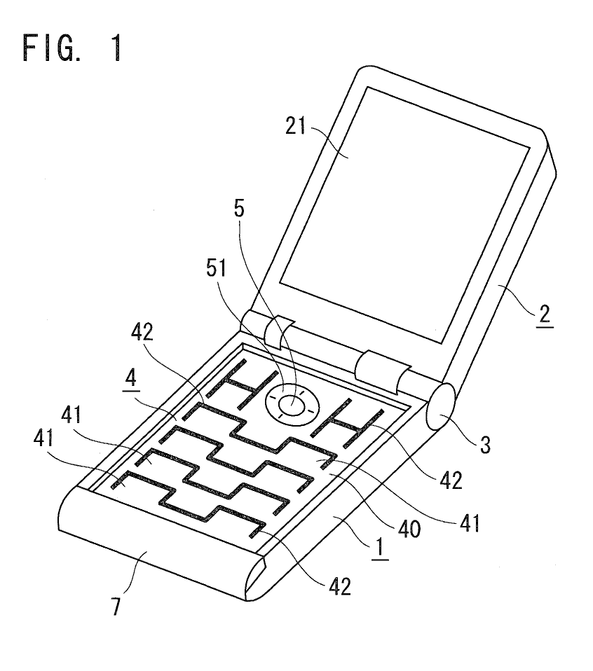

FIG. 1 shows a foldable portable telephone of the present invention, including an operation side body 1 and a display side body 2 that are openably and closably coupled to each other via a hinge mechanism 3. The operation side body 1 has a plurality of press operation portions 41, a decision button 5, and a cross key 51, which are arranged on its inner surface. The display side body 2 has a display 21 provided on its inner surface.

This portable telephone has multiple additional functions such as a music reproduction function, a television broadcasting reception function, a game function, etc. besides an ordinary telephone communication function.

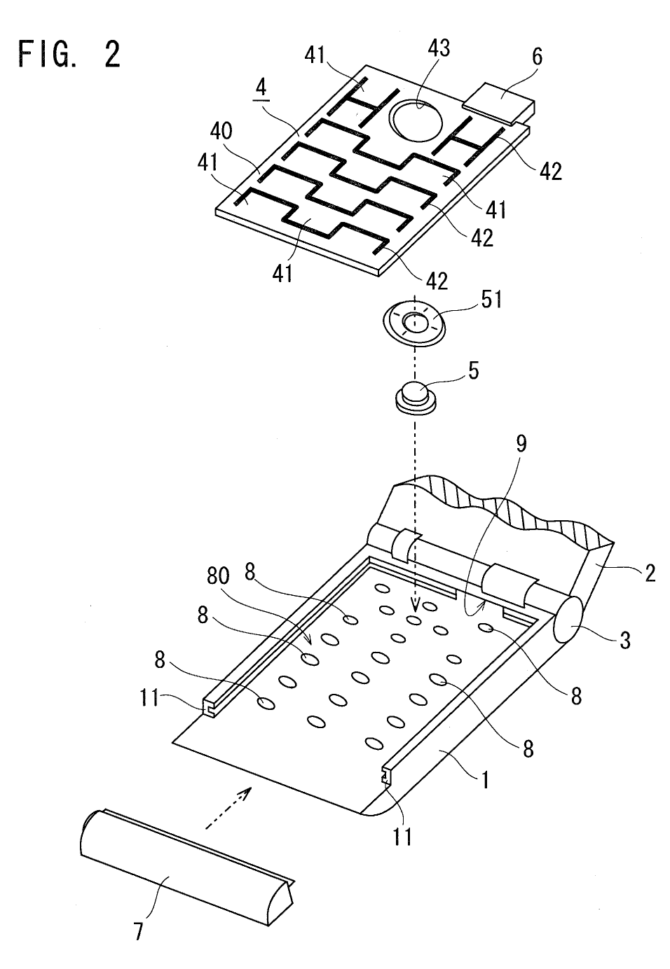

As shown in FIG. 2, the operation side body 1 has a key input device 80 including arrays of a plurality of switches 8. A key sheet 4 is detachably placed over the key input device 80.

The key sheet 4 includes a sheet body 40 made of sheet metal. The plurality of press operation portions 41 are for pressing and operating the respective switches 8, and defined by making a plurality of cuts 42 in the sheet body 40. In the drawing, the cuts 42 are drawn with a thick line for convenience of illustration.

The sheet body 40 of the key sheet 4 has a round window 43 through which the decision button 5 and the cross key 51 are to come out.

The operation side body 1 has a pair of right and left side walls 11, 11 formed on the opposite sides of the key input device 80. As shown in FIG. 4, the side walls 11, 11 each have a guide groove 12 on their inner side surface. This allows the key sheet 4 shown in FIG. 2 to be inserted and removed.

A stopper 7 is detachably attached to the operation side body 1 for stopping the key sheet 4 held by the side walls 11, 11 from coming out.

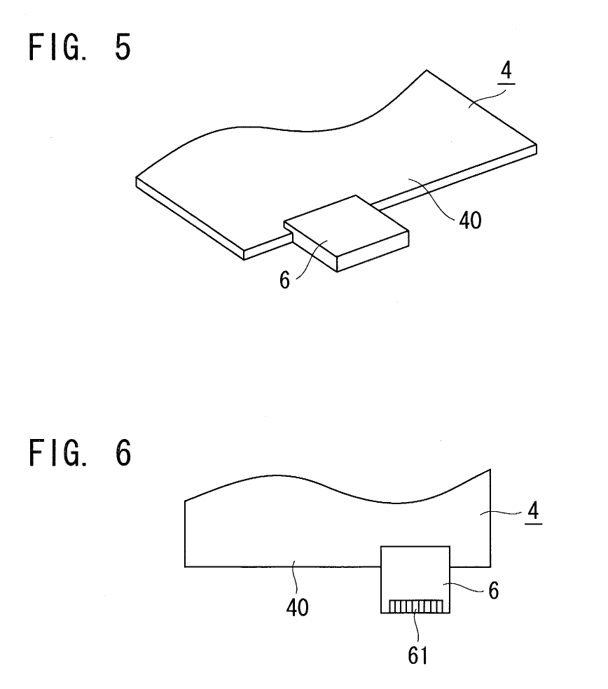

As shown in FIG. 5, a sheet identification chip 6 incorporating an IC memory is attached to the key sheet 4. As shown in FIG. 6, an electrode 61 is provided on the back of the sheet identification chip 6.

As shown in FIG. 2, a chip slot 9 is formed in the operation side body 1, into which the sheet identification chip 6 of the key sheet 4 is to be inserted. An interface (not shown) is provided at the back of the chip slot 9, to which the electrode 61 of the sheet identification chip 6 is to be connected.

As shown in FIG. 4, the switches 8 of the key input device 80 are formed in a dome-like shape, projecting from the surface of the operation side body 1. When the key sheet 4 is inserted into the guide grooves 12 of the side walls 11, 11 of the operation side body 1, the plurality of press operation portions 41, defined on the key sheet 4 as shown in FIG. 2, are opposed to the plurality of respective switches 8 on the operation side body 1. When the press operation portions 41 are pressed and operated, the press operation portions 41 are elastically restorably displaced, and press the switches 8 thereunder. This closes the contacts of the switches 8, and gives on signals.

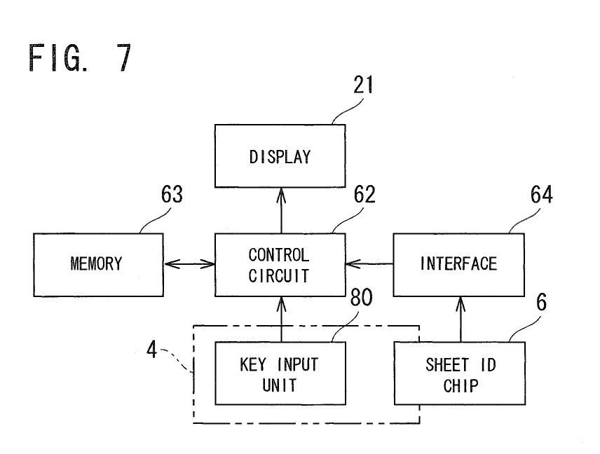

FIG. 7 shows an electrical configuration of the above-described portable telephone. The above-mentioned key input device 80, interface 64 and display 21 are connected to a control circuit 62 including a microcomputer, to which a memory 63 that stores various applications and information is also connected.

When the key sheet 4 is attached to the operation side body 1 as described above, the sheet identification chip 6 attached to the key sheet 4 is connected to the control circuit 62 via the interface 64.

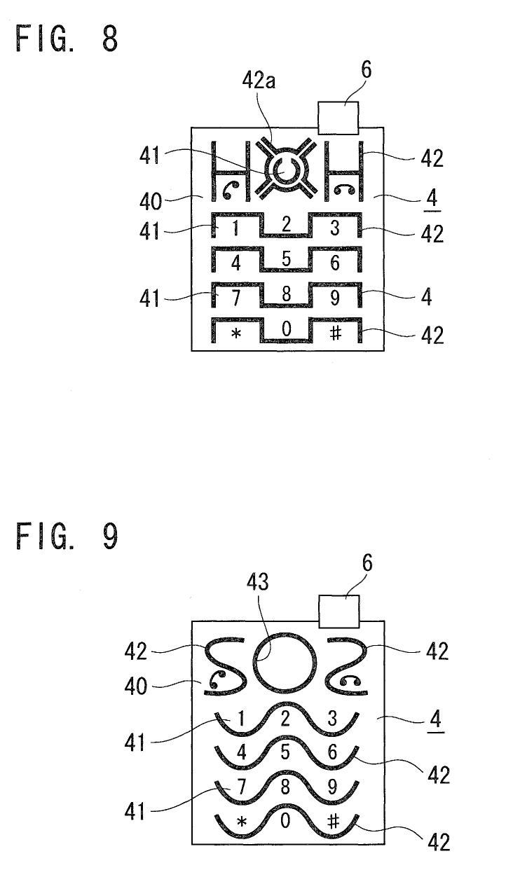

Examples of the key sheet 4 prepared for attachment in the case of activating an ordinary telephone communication function include that, as shown in FIG. 2, having a decision button 5 and cross key 51 for selection/decision operation, and that, as shown in FIG. 8, having a press operation portion 41 for selection/decision operation also defined by a cut 42a of the key sheet 4.

Also prepared may be that, as shown in FIG. 2, having cuts 42 formed like a polygonal line, and that, as shown in FIG. 9, having cuts 42 formed like a smooth wavy line.

A role (numeral, in the case of ten keys) assigned to each of the press operation portions 41 is printed on the surface of each of the press operation portions 41 of the key sheet 4.

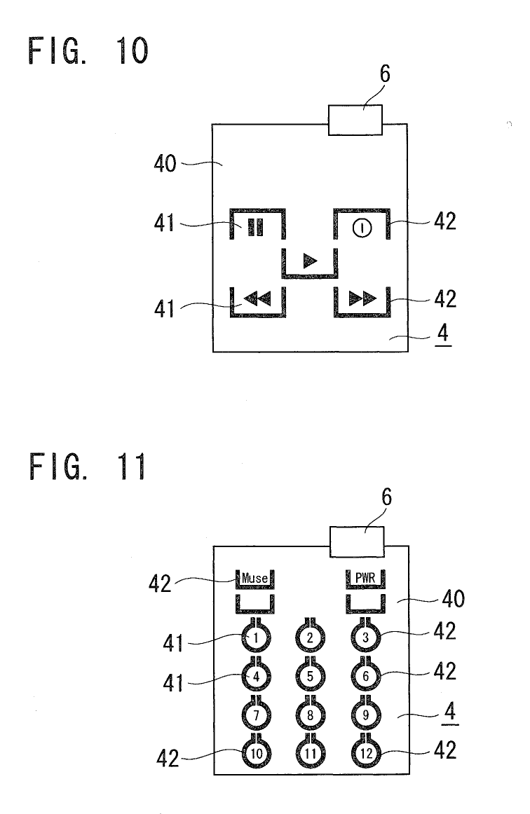

An example of the key sheet 4 prepared for attachment in the case of activating a music reproduction function is that, as shown in FIG. 10, having a plurality of press operation portions 41 formed for performing operations such as reproduction stop, pause, reproduction start, rewind, and forwarding. Each of the press operation portions 41 has a key indication printed thereon that indicates its role.

This key sheet 4 has formed thereon a limited number of press operation portions 41 necessary for performing the music reproduction function, and omits unnecessary press operation portions 41.

An example of the key sheet 4 prepared for attachment in the case of activating a television reception function is that, as shown in FIG. 11, having a plurality of press operation portions 41 formed for performing operations such as powering on, mute, channel selection, etc. Each of the press operation portions 41 has a key indication printed thereon that indicates its role.

The sheet identification chip 6 of the key sheet 4 has necessary information recorded thereon such as identification information of the key sheet 4, information of validity/invalidity of the switches 8 of the key input device 80, information on roles of the switches 8, information on change of image display control, etc.

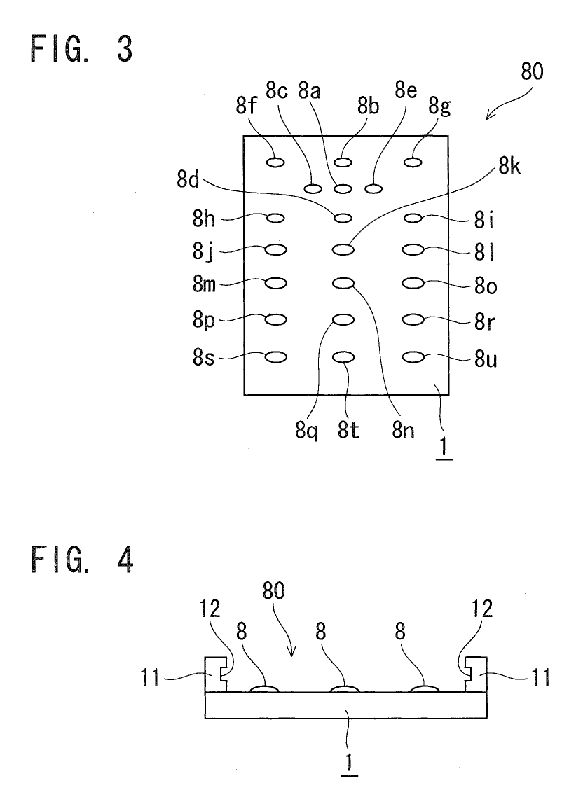

Information of validity/invalidity of the switches 8 and information on roles of the switches 8 are given with respect to all the switches 8a-8n, as shown in FIG. 3, included in the key input device 80. For example, the sheet identification chip 6 of the key sheet 4 shown in FIG. 10 used in performing the music reproduction function has recorded thereon the information that some of the switches 8a-8l, 8n, 8p, 8r and 8t of the key input device 80 are invalid.

In activating an ordinary telephone communication function, when the key sheet 4 shown in FIG. 2, for example, is attached, the sheet identification chip 6 of the key sheet 4 is connected to the control circuit 62 via the interface 64 shown in FIG. 7.

Accordingly, the control circuit 62 reads out all the information recorded on the sheet identification chip 6 via the interface 64, and recognizes the key sheet 4 based on the sheet identification information. The control circuit 62 then recognizes the validity/invalidity and roles of all the switches 8 included in the key input device 80, and, based on those recognized results, selects and starts the control procedure associated with the telephone communication function from multiple control procedures stored in the memory 63.

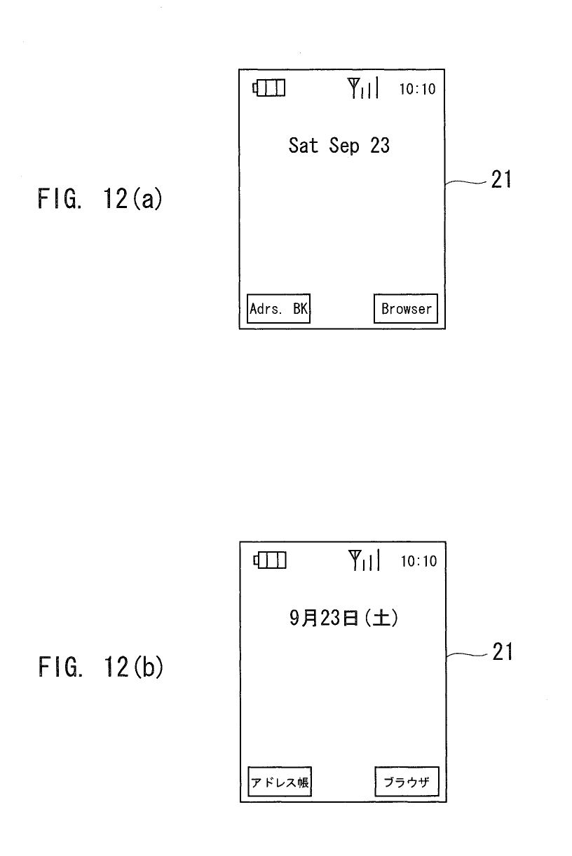

This causes the display 21 to display a standby screen in English as shown in FIG. 12(a). Operating necessary press operation portions 41 of the key sheet 4 in this state allows on-hook or off-hook dialing, input of telephone numbers, transmission and reception of messages, etc.

Alternatively, when the key sheet 4 shown in FIG. 8 is attached, the sheet identification chip 6 of the key sheet 4 is connected to the control circuit 62 via the interface 64 shown in FIG. 7. Accordingly, the control circuit 62 reads out all the information recorded on the sheet identification chip 6 via the interface 64, recognizes the key sheet 4 based on the sheet identification information, and starts the control procedure associated with the telephone communication function.

This results in the display 21 displaying a standby screen in Japanese as shown in FIG. 12(b). Operating necessary press operation portions 41 of the key sheet 4 in this state allows on-hook or off-hook dialing, input of telephone numbers, transmission and reception of messages, etc.

In addition, specific functions become available which are not provided to domestic specification portable telephones, but are provided to overseas specification portable telephones.

Alternatively, when the key sheet 4 shown in FIG. 9 is attached, the sheet identification chip 6 of the key sheet 4 is connected to the control circuit 62 via the interface 64 shown in FIG. 7. Accordingly, the control circuit 62 reads out all the information recorded on the sheet identification chip 6 via the interface 64, recognizes the key sheet 4 based on the sheet identification information, and starts the control procedure associated with the telephone communication function.

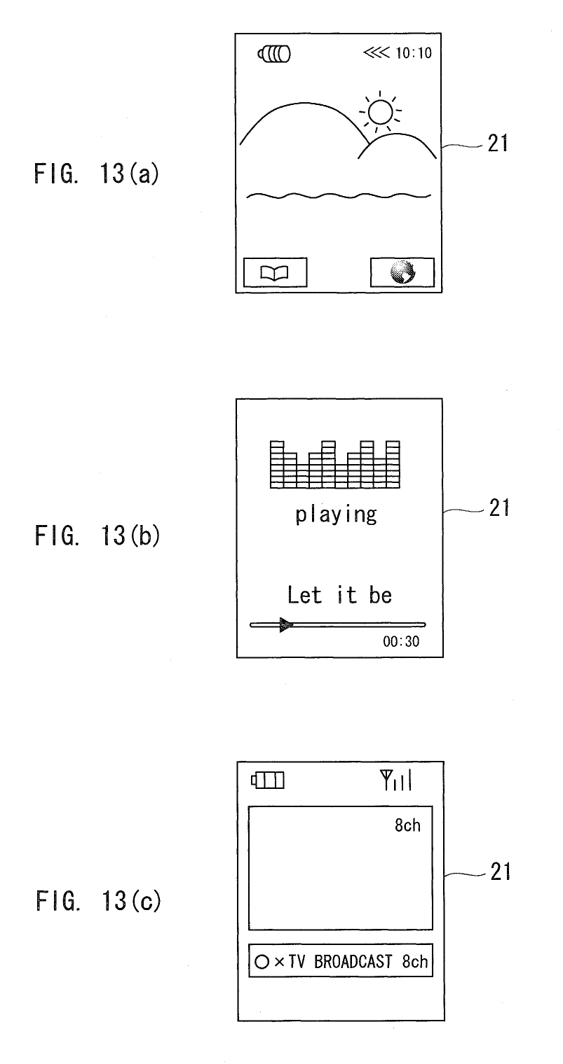

This results in the display 21 displaying a standby screen with illustration for children as shown in FIG. 13(a). Operating necessary press operation portions 41 of the key sheet 4 in this state allows on-hook or off-hook dialing, input of telephone numbers, transmission and reception of messages, etc.

Besides the telephone communication function, additional functions for children may be set. For example, because the music reproduction function may be unnecessary for children, a security function may be set instead. In this case, when the key sheet 4 is attached, the music reproduction function is invalidated, and the security function is validated.

Alternatively, when the key sheet 4 shown in FIG. 10 is attached, the sheet identification chip 6 of the key sheet 4 is connected to the control circuit 62 via the interface 64 shown in FIG. 7. Accordingly, the control circuit 62 reads out all the information recorded on the sheet identification chip 6 via the interface 64, recognizes the key sheet 4 based on the sheet identification information, and starts the control procedure associated with the music reproduction function.

This results in the display 21 displaying a screen for music reproduction as shown in FIG. 13(b). Operating necessary press operation portions 41 of the key sheet 4 in this state allows operations such as reproduction stop, pause, reproduction start, rewind, and forwarding.

Alternatively, when the key sheet 4 shown in FIG. 11 is attached, the sheet identification chip 6 of the key sheet 4 is connected to the control circuit 62 via the interface 64 shown in FIG. 7. Accordingly, the control circuit 62 reads out all the information recorded on the sheet identification chip 6 via the interface 64, recognizes the key sheet 4 based on the sheet identification information, and starts the control procedure associated with the television broadcast reception function.

This results in the display 21 displaying a screen for television broadcast reception as shown in FIG. 13(c). Operating necessary press operation portions 41 of the key sheet 4 in this state allows operations such as powering on, mute, channel selection, etc.

As described above, with the portable telephone of the present invention, users can switch the portable telephone to a desired function only by changing the key sheet 4, and activate that function by operating the press operation portions 41 having a key indication in accordance with the function.

It is only the key sheet 4 that is a part to be replaced. The key sheet 4 is extremely thin because it is simply made to include a sheet body 40 and press operation portions 41 defined therein. This allows the portable telephone to be made thinner. In addition, the replacement is easy.

Since the sheet body 40 of the key sheet 4 has the cuts 42 made to surround the press operation portions 41, light from a back light (not shown) passes through the cuts 42. This allows the press operation portions 41 to be easily recognized even at night.

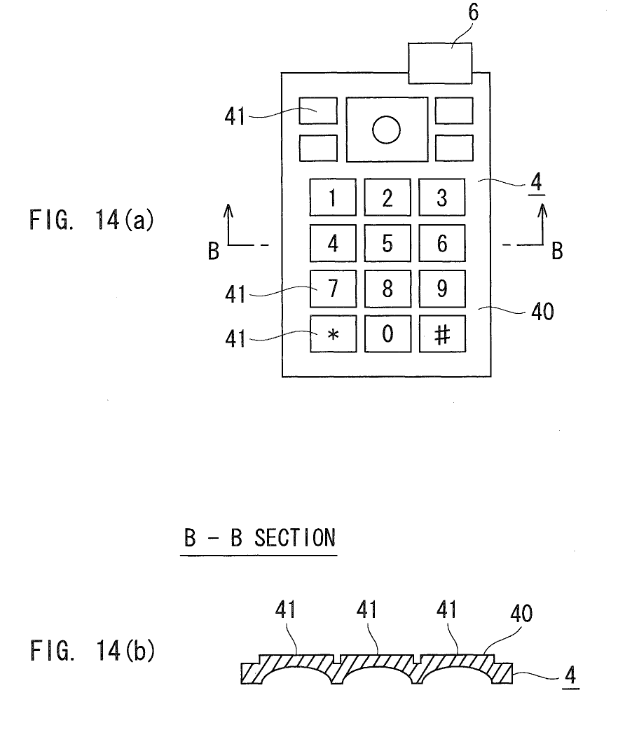

FIG. 14(a) and FIG. 14(b) show a key sheet 4 including a plurality of elastically restorably displaceable press operation portions 41 defined by thin portions formed in a synthetic resin made sheet body 40. In this case, the sheet body 40 is sufficiently strong so as to be insertable along the guide grooves 12 of the side walls 11, 11 of the operation side body 1.

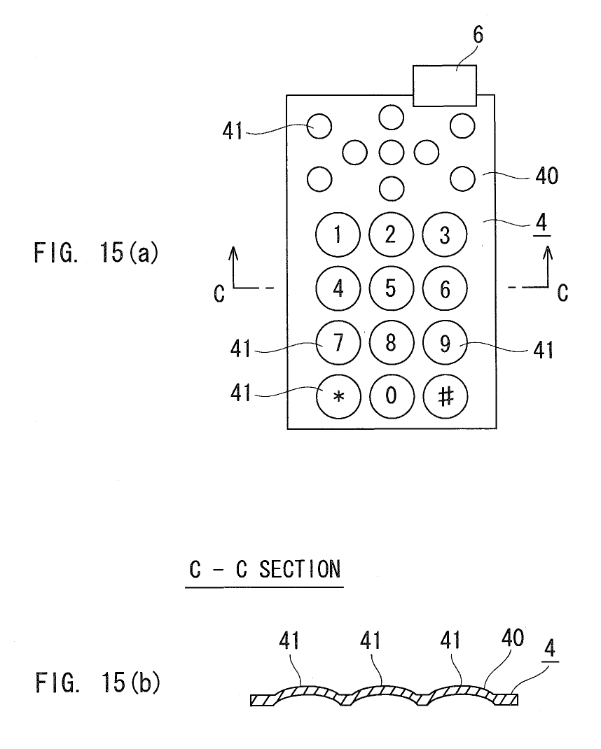

FIG. 15(a) and FIG. 15(b) show a key sheet 4 including a plurality of elastically restorably displaceable (invertible) press operation portions 41 defined by dome-like curved portions formed on a synthetic resin made sheet body 40. In this case, the surface of the sheet body 40 may be given a key indication including characters, numerals, symbols, etc. by embossing or printing. The sheet body 40 may have holes provided for the respective press operation portions 41 for passing light from a back light therethrough. The holes may be closed by an optically transparent waterproof sheet.

The present invention is not limited to the foregoing embodiment in construction but can be modified variously by one skilled in the art without departing from the spirit of the invention as set forth in the appended claims. Examples of change of functions by replacement of the key sheet 4 include portable telephones for business in which keys associated with camera photographing are invalidated, portable telephones for children with a call button or with a function for blocking harmful Internet information, and portable telephones for old people with only minimum operation keys. Other variations may be employed.

Examples of forming a plurality of press operation portions 41 on the key sheet 4 include making cuts 42 in the sheet body 40, forming thin portions in the sheet body 40, and forming dome-like curved portions on the sheet body 40. Other known variations for forming easily displaceable portions may be employed.

The key sheet 4 may be detachably attached to the operation side body 1 in various known manners, as well as with the use of the guide grooves 12 and the stopper 7 as in this embodiment.

Instead of the sheet identification chip 6, various known identification means may be employed such as a bar code, QR code, or a projection or like formation to which identification information is given. Instead of the contact interface 64, a noncontact interface may be employed.

What is claimed is:

1. A key input electronic device with a control circuit to which input signals in accordance with input operations are fed, the key input electronic device being controlled in operation by the control circuit and comprising:
a key input unit provided on the device body and including an array of a plurality of switches;
a key sheet including a sheet body detachably provided over the key input unit, the sheet body having a plurality of easily deformable press operation portions formed corresponding to the switches of the key input unit for pressing and operating the switches;
a sheet information portion provided on the key sheet; and
a sheet identifying portion for identifying the key sheet based on the sheet information portion,
wherein the key input unit and the sheet identifying portion are connected to the control circuit, and the control circuit is configured to change the operation based on the result identified by the sheet identifying portion.

2. The key input electronic device according to claim 1, wherein the key sheet has a plurality of easily displaceable portions defined by making a plurality of cuts in the sheet body, and the easily displaceable portions form the plurality of press operation portions.

3. The key input electronic device according to claim 1, wherein the key sheet has a plurality of easily displaceable portions defined by forming a plurality of thin portions in the sheet body, and the easily displaceable portions form the plurality of press operation portions.

4. The key input electronic device according to claim 1, wherein the key sheet has a plurality of easily displaceable portions defined by forming dome-like curved portions on the sheet body, and the easily displaceable portions form the plurality of press operation portions.

5. The key input electronic device according to claim 1, wherein the sheet information portion comprises a sheet identification chip comprising an IC memory.

6. The key input electronic device according to claim 5, wherein the sheet information portion is given information of validity/invalidity of the switches of the key input unit, information on rolls of the switches, and information on change of image display control, as well as sheet identification information.

7. The key input electronic device according to claim 1, wherein the device body includes side walls provided on the opposite sides of the key input unit and having respective guide grooves into which the key sheet is to be inserted, and a stopper for stopping the key sheet inserted into the guide grooves from coming out.
